(19) United States
(12) Patent Application Publication
(10) Pub. No.: US 2010/0186515 A1
(43) Pub. Date: Jul. 29, 2010

(54) PRESSURE DETECTION UNIT AND PRESSURE SENSOR

(75) Inventors: Toshinobu SAKURAI, Koza (JP); Kenta SATO, Chigasaki (JP)

Correspondence Address: HARNESS, DICKEY & PIERCE, P.L.C., P.O. BOX 828, BLOOMFIELD HILLS, MI, 48303, US

(73) Assignee: EPSON TOYOCOM CORPORATION, Tokyo (JP)

(21) Appl. No.: 12/690,290

(22) Filed: Jan. 20, 2010

(30) Foreign Application Priority Data
Jan. 27, 2009 (JP) 2009-015057
Nov. 9, 2009 (JP) 2009-255785

(51) Int. Cl. G01L 9/08; H01L 41/04

(52) U.S. Cl. 73/702; 310/323.21

(57) ABSTRACT

A pressure detection unit includes: a first piezoelectric resonator element having a vibrating portion and a pair of base portions connected to both ends of the vibrating portion; a second piezoelectric resonator element having a resonating arm and a base portion integrated with one end of the resonating arm; a diaphragm having a pair of supporting portions to which the base portions of the first piezoelectric resonator element are bonded; and a base disposed to be opposed to the diaphragm. In the pressure detection unit, the base portion of the second piezoelectric resonator element is joined to one of the base portions of the first piezoelectric resonator element in an identical plane.

### BACKGROUND

1. Technical Field

The present invention relates to a pressure detection unit and a pressure sensor in which a temperature sensing element for temperature detection is provided so as to improve pressure detecting accuracy and improve pressure sensitivity.

2. Related Art

Pressure indicators which utilize a relationship between stress applied to a piezoelectric resonator and resonance frequency change have been practically used. Pressure indicators include a double-ended tuning fork type piezoelectric resonator serving as the piezoelectric resonator so as to have excellent sensitivity with respect to stress, being able to detect height difference and depth difference from slight pressure difference.

JP-A-2007-327922, as a first example, discloses a pressure detection unit including a piezoelectric resonator element as a pressure sensing element.

FIG. 19A is a lateral sectional view of a pressure detection unit disclosed in the first example, and FIG. 19B is a sectional view taken along a Q-Q line of FIG. 19A.

A pressure detection unit 60 is an absolute pressure indicator including a diaphragm 61, a base 75 formed to be opposed to the diaphragm 61, and a piezoelectric resonator element 70 serving as a pressure sensing element.

The diaphragm 61 includes a thin portion 63 which deforms in response to pressure received from an upper direction of FIG. 19A and a frame portion 69 formed at a periphery of the thin portion 63. The diaphragm 61 includes a pair of supporting portions 65 for fixing the piezoelectric resonator element 70 on one surface of the thin portion 63. The piezoelectric resonator element 70 is supported by the supporting portions 65 at both fixed ends thereof. On the other surface of the thin portion 63, a protrusive portion 67 is formed on a part corresponding to a vibrating part 72 of the piezoelectric resonator element 70. The protrusive portion 67, which is formed by thickening a part of the thin portion 63, can prevent deformation of the part of the thin portion 63, and thus can prevent a central portion of the thin portion 63 from contacting with the piezoelectric resonator element 70 when pressure is applied.

A double-ended tuning fork type vibrating element is used as the piezoelectric resonator element 70. The double-ended tuning fork type vibrating element includes fixing ends 71 at both ends thereof and two vibrating beams formed between the fixing ends 71. The double-ended tuning fork type vibrating element has such a characteristic that when extensional stress (tensile stress) or compressive stress is applied thereto, resonance frequency thereof changes nearly in proportion to applied stress.

In the pressure detection unit 60 shown in FIGS. 19A and 19B, the fixing ends 71 of the piezoelectric resonator element (double-ended tuning fork type vibrating element) 70 are fixed on placing surfaces 66 of the pair of supporting portions 65 formed on the thin portion 63 of the diaphragm 61. When pressure is applied on an upper part of the diaphragm 61, the thin portion 63 bends and deforms toward a lower direction of FIG. 19A. The placing surfaces 66 of the supporting portions 65 incline toward an outside of the thin portion 63 in accordance with a deformation state of the thin portion 63. Therefore, an interval between the placing surfaces 66 becomes large, whereby tensile stress is applied to the vibrating part 72 of the piezoelectric resonator element (double-ended tuning fork type vibrating element) 70 fixed on the placing surfaces 66.

When the tensile stress is applied to the vibrating part 72, resonance frequency of the piezoelectric resonator element (double-ended tuning fork type vibrating element) 70 increases. Then a detection part which is not shown detects this frequency change so as to obtain stress change based on the frequency change, being able to detect pressure applied on the diaphragm 61.

However, a frequency temperature characteristic of the piezoelectric resonator element (double-ended tuning fork type vibrating element) 70 is expressed by an upward protrusive quadratic curve. Accordingly, when the resonator element (double-ended tuning fork type vibrating element) 70 is used in an environment having large temperature change, an error is generated on stress detecting accuracy disadvantageously. JP-A-2006-284301, JP-A-2006-324652, and JP-A-2008-111761, as second, third, and fourth examples, disclose a device which is provided with a thermistor or a transistor as a temperature detecting element (temperature sensing element) to detect a temperature based on an electrical characteristic change thereof and feed it back to a control unit.

Provision of a thermistor or a transistor as the temperature sensing element to the pressure detection unit 60 is easily thought up.

For example, an output of a temperature sensor 82 is coupled to an A/D converter 85 and an output of the A/D converter 85 is coupled to one input of a processing device 86 in a pressure sensor 80 as shown in a block diagram of FIG. 20. In addition, a stress detection unit 81 is coupled to an oscillation circuit 83 and an output of the oscillation circuit 83 is coupled to the other input of the processing device 86 through a frequency counter 84. The processing device 86 calculates a signal received from the A/D converter 85 so as to obtain a temperature, and corrects a frequency temperature characteristic of the stress detection unit 81 based on the obtained temperature. Thus only stress applied on the stress detection unit 81 is detected highly accurately. Then pressure applied to the diaphragm is calculated while taking the structure of the diaphragm into an account.

JP-B-61-29652 discloses an example of an analog type temperature indicator, which is a thermistor for example, as the temperature sensor 82 shown in FIG. 20. As shown in FIG. 21, this temperature indicator 90 is structured such that a bridge circuit is formed by using resistors R1, R2, R3, and R4, a connecting point of the resistors R1 and R3 and a connecting point of the resistors R2 and R4 are respectively coupled to two inputs of an OP amplifier 92, and an output of the OP amplifier 92 is coupled to an input of an A/D converter 93. The temperature indicator 90 obtains a temperature by processing an output of the A/D converter 93 in a processing circuit 94. Here, the resistor R3 is a circuit which is obtained by connecting a variable resistance unit Rv31 in series to a parallel circuit of a variable resistance unit Rv32 and a thermistor Th.

However, the thermistor has an exponential temperature-resistance characteristic, and current needs to be applied from a current source 91, for example, in temperature measurement. In addition, the A/D converter consumes large amount of current. For example, a temperature sensor including a thermistor consumes current of about 200 μA, and a 12 bit A/D converter consumes current of about 300 μA. Further, when an analog quantity is converted into a digital value, temperature detecting accuracy is degraded due to a noise and the like. Thus, the analog temperature-detecting method has a problem of measurement accuracy and a problem of large current consumption (about 500 μA).

In order to solve these problems, an acceleration sensor in which a tuning fork type quartz crystal vibrating element is used as a temperature sensor is proposed. A frequency temperature characteristic of a double-ended tuning fork type quartz crystal vibrating element is equal to that of the tuning fork type quartz crystal vibrating element. JP-A-53-2097, JP-A-54-158150, JP-A-58-208632, JP-B-62-58173, and JP-A-2005-197946, as sixth, seventh, eighth, ninth, and tenth examples, disclose a relationship between a cutting angle of a substrate of a tuning fork type quartz crystal vibrating element and a frequency temperature characteristic of the vibrating element. In these examples, a substrate cut by an angle which is obtained by rotating XY plane (Z plate) about X axis by θ (0° to ±15°, 15° to 25°, 30° to 60°, or the like) is used.

The frequency temperature characteristic of the double-ended tuning fork type quartz crystal vibrating element is expressed by an upward protrusive quadratic curve, and the peak of the curve is set to be about a normal temperature. Therefore, frequency change due to a temperature is small.

Further, JP-B-6-103231 as an eleventh example discloses an acceleration sensor in which a tuning fork type vibrating element, a double-ended tuning fork type vibrating element, and a cantilever are integrated, and process to use the tuning fork type vibrating element as a temperature sensor. With such the structure, temperature-compensated acceleration sensor having high accuracy can be realized.

However, JP-A-2008-170167, JP-A-2008-170203, JP-A-2008-197031, JP-A-2008-197032, and JP-A-2008-224345, as twelfth, thirteenth, fourteenth, fifteenth, and sixteenth examples, disclose a relationship between stress applied on a double-ended tuning fork type quartz crystal vibrating element and a peak temperature of a frequency temperature characteristic, and disclose that the peak temperature shifts to a lower temperature side when tensile stress is applied to the vibrating element and the peak temperature shifts to a higher temperature side when compressive stress is applied.

In the acceleration sensor disclosed in the eleventh example, the peak temperature is set at an intermediate point of an operating temperature range so as to make frequency change of the double-ended tuning fork type quartz crystal vibrating element small in the operating temperature range. Even though a cutting angle of a quartz crystal substrate is set as above, when stress load corresponding to acceleration is generated inside the double-ended tuning fork type quartz crystal vibrating element, the peak temperature of the frequency temperature characteristic disadvantageously shifts to a higher temperature side due to compressive stress generated in the vibrating element, as shown in FIG. 25. Further, since intensity of the compressive stress changes in accordance with an amount of acceleration, a shifting amount toward the higher temperature side also changes. Even if temperature compensation of an acceleration sensor is attempted by a temperature sensor, the double-ended tuning fork type quartz crystal vibrating element operates in a range, apart from the peak temperature of the frequency temperature characteristic, of an operating temperature range. That is, acceleration is detected in a range in which the frequency temperature characteristic linearly changes. Therefore, slight temperature change causes frequency change of the double-ended tuning fork type quartz crystal vibrating element, so that a noise of the frequency change, corresponding to the temperature change, overlaps with detected acceleration disadvantageously.

### SUMMARY

An advantage of the present invention is to provide a pressure sensor in which temperature detecting accuracy is improved and a temperature characteristic of the double-ended tuning fork type vibrating element is corrected so as to improve measurement accuracy of the pressure sensor and substantially reduce current consumption.

The present invention is intended to solve at least part of the mentioned problems and may be implemented by the following aspects of the invention.

A pressure detection unit according to a first aspect of the invention includes: a first piezoelectric resonator element having a vibrating portion and a pair of base portions connected to both ends of the vibrating portion; a second piezoelectric resonator element having a resonating arm and a base portion integrated with one end of the resonating arm; a diaphragm having a pair of supporting portions to which the base portions of the first piezoelectric resonator element are bonded; and a base disposed to be opposed to the diaphragm. In the pressure detection unit, the base portion of the second piezoelectric resonator element is joined to one of the base portions of the first piezoelectric resonator element in an identical plane.

Thus, the base portion of the first piezoelectric resonator element and the base portion of the second piezoelectric resonator element are identical, being able to downsize the pressure detection unit.

Further, the second piezoelectric resonator element detecting a temperature is formed to contact with the first piezoelectric resonator element detecting pressure (stress), so as to be able to precisely detect the temperature of the first piezoelectric resonator element as a digital quantity. Therefore, the frequency change due to the temperature change of the first piezoelectric resonator element can be corrected so as to substantially improve accuracy in measuring pressure of a measured medium.

Further, power consumption can be substantially reduced compared to an analog temperature-detecting method.

A pressure detection unit according to a second aspect of the invention includes: a first piezoelectric resonator element layer including a first piezoelectric resonator element having a vibrating portion and a pair of base portions connected to both ends of the vibrating portion, a frame portion surrounding the first piezoelectric resonator element, and a supporting piece connecting the frame portion and each of the base portions; a second piezoelectric resonator element having a resonating arm and a base portion integrated with one end of the resonating arm; a diaphragm layer including a pair of supporting portions that cover one main surface of the first piezoelectric resonator element layer and are respectively bonded to the base portions of the first piezoelectric resonator element; and a base layer covering the other main surface of the first piezoelectric resonator element layer. In the pressure detection unit, the base portion of the second piezoelectric resonator element is joined to a side of the frame portion, and the second piezoelectric resonator element and the first piezoelectric resonator element are disposed on the same level.

In such the structure, the pressure detection unit can be formed by a process proceeding using a large sized wafer, achieving downsizing and cost reduction of the detection unit.

Further, the pressure detection unit is fabricated such that a frame portion of the diaphragm, a frame portion of the base, and an outer frame which couples the first and second piezoelectric resonator elements are adjusted to each other. Thus fabricating accuracy is improved and the fabrication is simple.

Further, since the temperature of the first piezoelectric resonator element can be precisely detected as a digital quantity, an error, caused by the temperature change, of stress detected by the first piezoelectric resonator element can be corrected. Thus, pressure measurement accuracy is substantially improved. In addition, this is substantially effective to reduction of power consumption.

In the pressure detection unit of the first or second aspect, the first piezoelectric resonator element may have a frequency temperature characteristic that is expressed by an upward protrusive quadratic curve, and a cutting angle of the first piezoelectric resonator element may be set so that a peak temperature of the frequency temperature characteristic is in an operating temperature range when a load is applied.

Thus, the peak temperature of the frequency temperature characteristic can be set within the operating temperature range by appropriately adjusting the cutting angle of the first piezoelectric resonator element, being able to improve detecting accuracy of the pressure detection unit even though the temperature changes.

In the pressure detection unit of the first or second aspect, the vibrating portion may be composed of at least one column beam.

The pressure detection unit using a double-ended tuning fork type piezoelectric vibrating element is substantially superior to a pressure (stress) detection unit having pressure (stress) detecting sensitivity in other vibration modes such as thickness-sliding vibration, longitudinal vibration, and surface acoustic wave vibration. Thus, a pressure detection unit with high sensitivity can be structured.

In the pressure detection unit of the first or second aspect, the second piezoelectric resonator element may be a tuning fork type vibrating element.

Thus, the tuning fork type piezoelectric vibrating element is used for detecting the temperature of the stress detection unit, substantially improving temperature detection accuracy. Furthermore, power consumption for the temperature detection can be extremely reduced.

A pressure detection unit according to a third aspect of the invention includes: a piezoelectric resonator element having a vibrating portion and a pair of base portions connected to both ends of the vibrating portion; a diaphragm having a pair of supporting portions to which the base portions of the piezoelectric resonator element are bonded; and a base disposed to be opposed to the diaphragm. In the pressure detection unit, the piezoelectric resonator element has a frequency temperature characteristic that is expressed by an upward protrusive quadratic curve, and a cutting angle of the piezoelectric resonator element is set so that a peak temperature of the frequency temperature characteristic is in an operating temperature range when a load is applied.

The peak temperature of the frequency temperature characteristic can be set within the operating temperature range in an operating state by appropriately adjusting a cutting angle of the resonator element, being able to improve detecting accuracy of the pressure detection unit even though the temperature changes.

A pressure sensor according to a fourth aspect of the invention includes: the pressure detection unit according to the first, second, or third aspect; and a stress detection circuit. In the pressure sensor, the stress detection circuit includes: a first oscillation circuit operating the first piezoelectric resonator element of the pressure detection unit, a second oscillation circuit operating the second piezoelectric resonator element, a first frequency counter counting frequency of a stress detection signal outputted from the first oscillation circuit, a second frequency counter counting frequency of a temperature detection signal outputted from the second oscillation circuit, and a processing circuit correcting a frequency count signal outputted from the first frequency counter by a frequency count signal outputted from the second frequency counter.

In the structure, the frequency of the first piezoelectric resonator element is corrected based on the temperature signal of the second piezoelectric resonator element, being able to improve the pressure measurement accuracy and substantially reduce current consumption.

A pressure sensor according to a fifth aspect of the invention includes: the pressure detection unit of the first, second, or third aspect; and a stress detection circuit. In the pressure sensor, the stress detection circuit includes: an oscillation circuit operating one of the first and second piezoelectric resonator elements through a switcher, a frequency counter counting frequency of an output signal of one of the first and second piezoelectric resonators outputted from the oscillation circuit, and a processing circuit correcting a frequency count signal outputted from the frequency counter.

With this structure, a downsized pressure sensor can be achieved and current consumption can be substantially reduced.

### BRIEF DESCRIPTION OF THE DRAWINGS

The invention will be described with reference to the accompanying drawings, wherein like numbers reference like elements.

FIGS. 1A and 1B are exploded perspective views of a pressure detection unit for an analysis. FIG. 1B shows a diaphragm substrate. FIG. 1B shows a double-ended tuning fork type vibrating element substrate. FIG. 1C shows elastic constants. FIG. 1E shows a temperature relating expression of the elastic constants.

FIG. 2 shows a pressure (stress) P-frequency f characteristic.

FIG. 3 shows a frequency temperature characteristic obtained by using stress as a parameter.

FIG. 4 shows a relationship between a temperature and a sensitivity change ratio in which a curve shown by diamond shaped symbols: ♦ is obtained by calculation and a curve shown by square shaped symbols: ▪ is obtained by measurement.

FIG. 5 shows a frequency temperature characteristic, in a case of loading 0 atmosphere on a pressure detection unit and a case of loading 1 atmosphere on the same, obtained by using a finite element method.

FIG. 6 shows a frequency temperature characteristic, in a case of loading 0 atmosphere on a pressure detection unit and a case of loading 1 atmosphere on the same, obtained by measurement.

FIG. 7A shows a relationship between pressure P of the pressure detection unit and resonance frequency f. FIG. 7B shows frequency temperature characteristics when a double-ended tuning fork type quartz crystal vibrating element receives no load and when the vibrating element receives a load.

FIGS. 8A and 8B show the stress detection unit of the first embodiment. FIG. 8A is a sectional view and taken along a Q2-Q2 line, and FIG. 8B is a sectional view taken along a Q1-Q1 line.

FIGS. 9A and 9B are respectively a sectional view and a plan view showing a structure of a diaphragm.

FIGS. 10A and 10B are respectively a sectional view and a plan view showing a structure of a base.

FIG. 11A is a plan view for explaining a vibration mode of a double-ended tuning fork type piezoelectric resonator, FIG. 11B is a plan view for explaining an electrode structure of the resonator, and FIG. 11C is a wiring diagram of the electrode.

FIG. 12A is a sectional view of a stress detection unit of a second embodiment, FIG. 12B is a plan view of a framed piezoelectric resonator element, and FIG. 12C is a lateral view of FIG. 12B.

FIG. 13A is a plan view showing a lead electrode of the framed piezoelectric resonator element and FIG. 13B is a sectional view of a stress detection unit of the second embodiment including the framed piezoelectric resonator element of FIG. 13A.

FIG. 14A is a plan view showing a framed piezoelectric resonator element serving as a complex piezoelectric resonator element, and FIG. 14B is a lateral view of FIG. 14A.

FIG. 15A is a plan view of a diaphragm, FIG. 15B shows a relationship between a dimension L of a thin portion of the diaphragm and stress sensitivity of the diaphragm, and FIG. 15C shows a relationship between a dimension W of the thin portion and stress sensitivity.

FIG. 16A is a sectional view of a stress detection unit of a third embodiment, FIG. 16B is a plan view of a framed piezoelectric resonator element, and FIG. 16C is a lateral view of FIG. 16B.

FIG. 17 is a perspective view showing a schematic structure of another stress detection unit.

FIGS. 18A and 18B are block diagrams showing structures of stress sensors.

FIG. 19A is a sectional view of a related art stress detection unit and FIG. 19B is a sectional view taken along a Q-Q line of FIG. 19A.

FIG. 20 is a block diagram showing a structure of a stress sensor.

FIG. 21 is a circuit diagram showing a structure of a related art temperature instrument.

FIG. 22 shows a relationship between a tuning fork type piezoelectric resonator and a crystal axis.

FIG. 23 shows a relationship between a cutting angle θ of the tuning fork type piezoelectric resonator and a primary coefficient α.

FIG. 24 shows a frequency temperature characteristic of a tuning fork type piezoelectric resonator for temperature measurement.

FIG. 25 shows frequency temperature characteristics of a double-ended tuning fork type quartz crystal vibrating element at loaded time and the vibrating element at no load time.

### DESCRIPTION OF EXEMPLARY EMBODIMENTS

Embodiments of the present invention will now be described with reference to the accompanying drawings.

First, the inventor performed analysis estimation on a relationship between stress applied on a double-ended tuning fork type vibrating element and a shift of a peak temperature. The twelfth, thirteenth, fourteenth, fifteenth, and sixteenth examples disclose a relationship between stress applied on a double-ended tuning fork type vibrating element and a so-called peak temperature of a frequency temperature characteristic expressed by a quadric curve. In the relationship of the examples, the peak temperature shifts to a lower temperature side when extensional stress is applied, and the peak temperature shifts to a higher temperature side when compressive stress is applied. However, according to an analysis result of the inventor, it was proved that a shifting direction of the peak temperature was opposite.

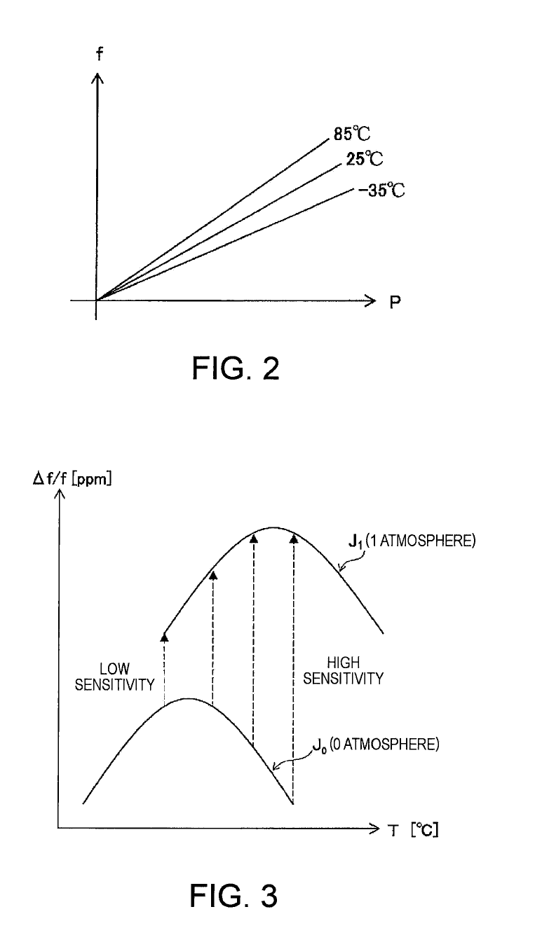

First, a phenomenon that a peak temperature of a frequency temperature characteristic of a pressure detection unit including a double-ended tuning fork type vibrating element shifts to a higher side will be qualitatively described. Referring to FIG. 2 showing a pressure (stress) P-frequency f characteristic of a pressure detection unit, pressure-frequency sensitivity (df/dP) changes depending on a temperature T of the pressure detection unit. The pressure-frequency sensitivity (df/dP) is smaller at a low temperature (−35 C.°) and is larger at a high temperature (85° C.) than the sensitivity at a normal temperature (25 C.°). In addition to this phenomenon, extensional (tensile) stress is applied to the double-ended tuning fork type quartz crystal vibrating element.

FIG. 3 is a diagram for explaining a phenomenon that a peak temperature of a frequency temperature characteristic (temperature T-frequency Δf/f characteristic) of the pressure detection unit shifts to a higher temperature side in a case where pressure applied on the pressure detection unit changes from 0 atmosphere to 1 atmosphere. In a case of a pressure detection unit of which a sealed space is vacuumed, when pressure applied to a diaphragm is 0 atmosphere, no stress is applied on a double-ended tuning fork type quartz crystal vibrating element of the pressure detection unit.

When the pressure applied to the diaphragm is changed to 1 atmosphere, for example, extensional (tensile) stress is applied on the double-ended tuning fork type quartz crystal vibrating element, increasing frequency of the vibrating element. At this time, the pressure-frequency sensitivity (df/dP) is low at a low temperature and the pressure-frequency sensitivity (df/dP) is high at a high temperature as shown in FIG. 2. When these two phenomena are added, the frequency temperature characteristic (temperature T-frequency Δf/f characteristic) at 0 atmosphere shown by J₀ shifts to a frequency temperature characteristic at 1 atmosphere shown by J₁, as shown in FIG. 3.

A result obtained by analyzing the pressure detection unit including the double-ended tuning fork type vibrating element by a finite element method will be next described.

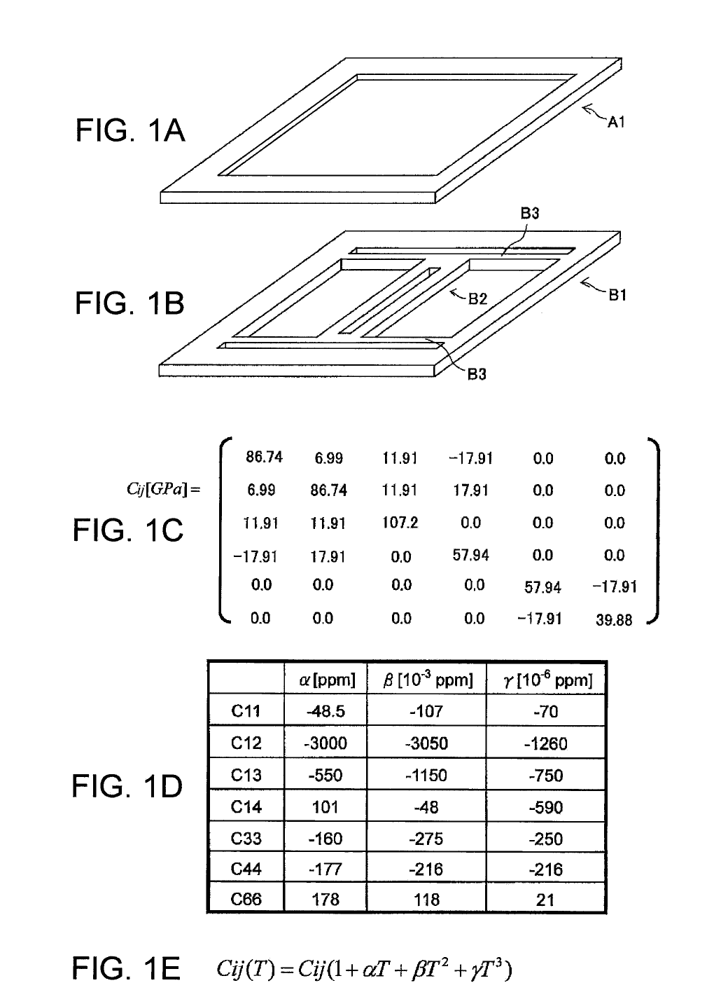

FIGS. 1A and 1B are perspective views showing a structure of the pressure detection unit used in the analysis. FIG. 1A shows a diaphragm substrate A1 and FIG. 1b shows a double-ended turning fork type vibrating element substrate B1. A double-ended turning fork type vibrating element B2 is supported by supporting pieces B3 so as to be held on the double-ended turning fork type vibrating element substrate B1. In the analysis, the diaphragm substrate A1 and the double-ended tuning fork type vibrating element substrate B1 were made of quartz crystal, a density was 2.65×10³ [kg/m³], and a Poisson's ratio was 0.135.

The analysis of the pressure detection unit composed of elements shown in FIGS. 1A and 1B was performed by using the finite element method. Constant numbers shown in FIG. 1C were used as an elastic constant (Young's modulus) Cij, relating a distortion and stress, of a motion equation used in the analysis of the pressure detection unit. The elastic constant (Young's modulus) Cij of quartz crystal has anisotropy and temperature dependency. Therefore, an elastic constant at an arbitrary temperature T was obtained by using the following approximate expression (1).

Cij(T)=Cij(1+αT+βT²+yT³) (1)

A first order coefficient α, a second order coefficient β, and a third order coefficient y of the elastic constant Cij in the expression (1) were respectively constant numbers shown in FIG. 1D.

A cause that the pressure-frequency sensitivity (df/dP) changes depending on a temperature as shown in FIG. 2 was examined. The elastic constant Cij was expressed by a function of the temperature T as the expression (1) and resonance frequency of the pressure detection unit was analyzed by the finite element method.

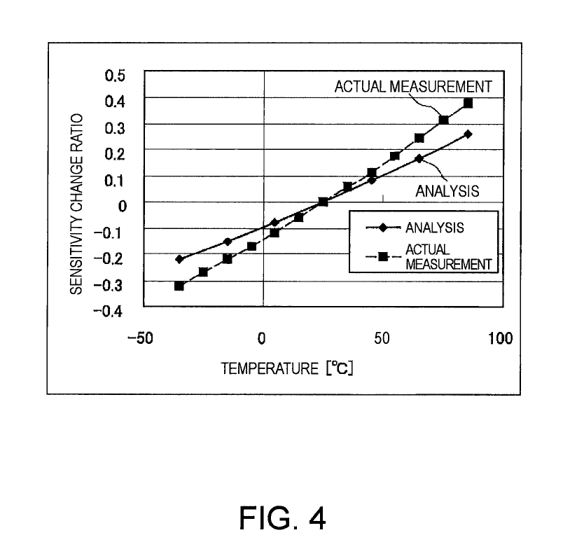

FIG. 4 is a diagram showing a relationship between the temperature T and sensitivity change ratio. A frequency of the pressure detection unit at 0 atmosphere is denoted by f₀, a frequency at 1 atmosphere is denoted by f₁, and sensitivity change ratio defined as |f₀−f₁|/f₁ is set to be 0 at 25 C.°. A temperature T-sensitivity change ratio curve obtained by the analysis in which the temperature T was changed is denoted by diamond shaped symbols: ♦. A curve expressed by square shaped symbols: ▪ is a temperature T-sensitivity change ratio curve obtained by measuring a pressure detection unit experimentally produced.

The peak temperature of the frequency temperature characteristic of the pressure detection unit changes depending on applied pressure because a first order constant of a polynomial expressing the frequency temperature characteristic changes. When the temperature increases, the elastic constant Cij of quartz crystal becomes small, increasing the sensitivity change ratio shown in FIG. 4. Since the sensitivity change ratio increases nearly linearly with respect to increase of the temperature T, the first order constant of the polynomial expressing the frequency temperature characteristic of the pressure detection unit changes. As a result, the peak temperature is seemed to shift.

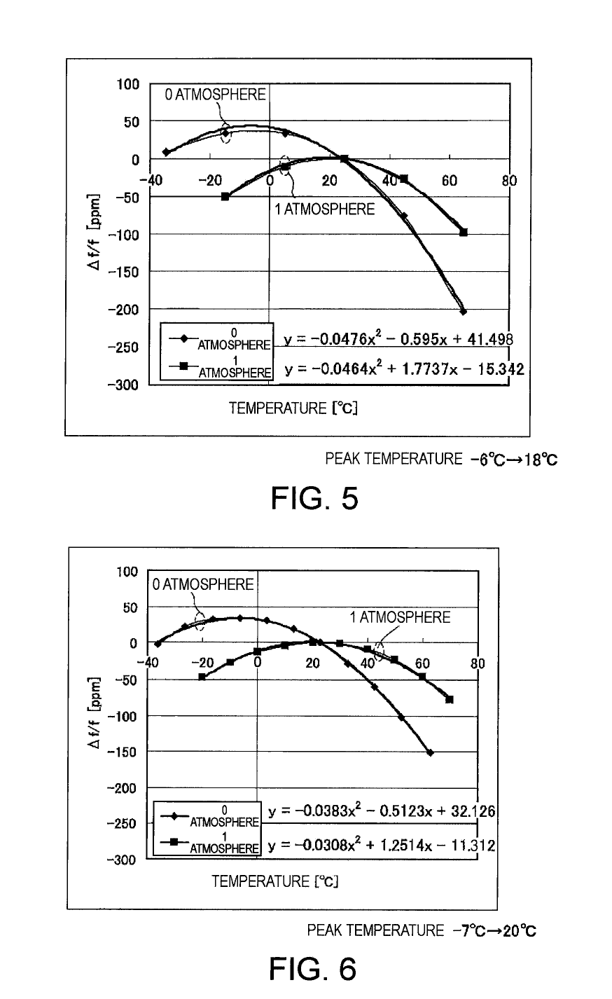

FIG. 5 is a diagram showing frequency temperature characteristics of the pressure detection unit obtained in an analysis when pressure applied on the diaphragm was set to be 0 atmosphere and when the pressure was set to be 1 atmosphere. The frequency change Δf/f of the pressure detection unit was calculated by changing the temperature T in each atmosphere. The case of 0 atmosphere is shown by diamond shaped symbols: ♦, and the case of 1 atmosphere is shown by square shaped symbols: ▪. FIG. 5 shows a curve (thin line) obtained by connecting the temperature T and calculated frequency change Δf/f at 0 atmosphere and 1 atmosphere by a smooth line, and a curve (heavy line) obtained by approximating the temperature T and the frequency change Δf/f by a polynomial, in a overlapping manner. It was proved that the peak temperature of the frequency temperature characteristic at 0 atmosphere was −6° C. but the peak temperature shifted to a higher temperature side to be 20° C., from the analysis. Polynomial expressions y (=Δf/f) expressing the frequency temperature characteristics of the pressure detection unit at 0 atmosphere and 1 atmosphere are expressed by quadratic expressions on x (=temperature T) and shown on a lower part of the drawing.

FIG. 6 shows curves obtained by measuring a frequency temperature characteristic of the experimentally produced pressure detection unit on which loads of 0 atmosphere and 1 atmosphere were applied. A case of 0 atmosphere is shown by diamond shaped symbols: ♦, and a case of 1 atmosphere is shown by square shaped symbols: ▪. The peak temperature of the frequency temperature characteristic was −7C.° in the case of 0 atmosphere but the peak temperature shifted to 20 C.° in the case of 1 atmosphere. Polynomial expressions y (=Δf/f) expressing the frequency temperature characteristics of the pressure detection unit at 0 atmosphere and 1 atmosphere are expressed by quadratic expressions on x (=temperature T) and shown on a lower part of the drawing. In comparison between the analysis result shown in FIG. 5 and the measurement result shown in FIG. 6, it was proved that a shifting amount of the peak temperature to a higher temperature side agreed with the analysis result with a small percent error in a case where pressure (1 atmosphere) was applied to the pressure detection unit.

From the analysis result and the measurement result, it is proved that the peak temperature of the frequency temperature characteristic changes because of the change of the first order coefficient of a polynomial expressing the frequency temperature characteristic.

In the present invention, a polynomial expression expressing the frequency temperature characteristic of the pressure detection unit was defined as a first approximation expression f so as to be expressed as the following third order polynomial expression (2).

f=a₁T³+a₂T²+a₃T+a₄ (2)

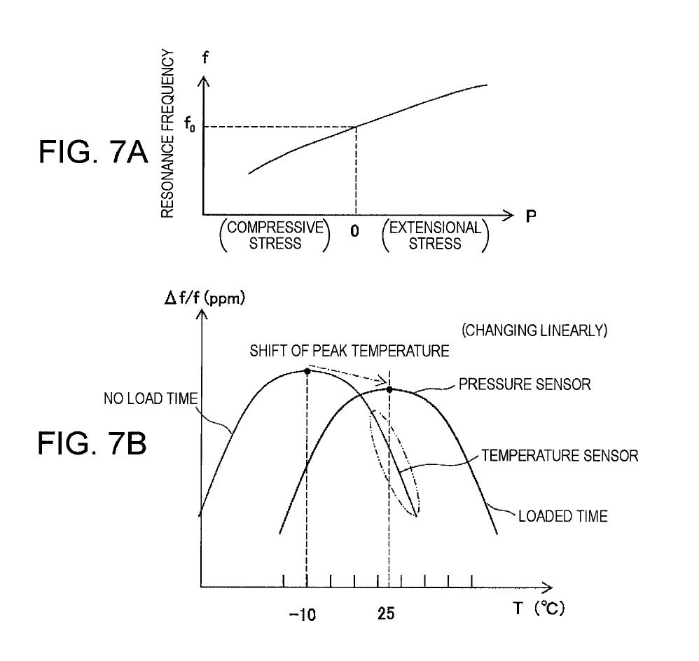

FIG. 7A shows a curve expressing a pressure P—frequency f characteristic which shows change of resonance frequency f when pressure (stress) P is applied on the pressure detection unit. A polynomial expression expressing the pressure frequency characteristic was defined as a second approximate expression P so as to be expressed by the following third order polynomial expression (3).

P=b₁f³+b₂f²+b₃f+f_{c} (3)

Here, fc denotes a frequency temperature characteristic in a case where pressure of 1 atmosphere, for example, is applied on the pressure detection unit. A first order coefficient b3 in the expression (3) exhibits temperature dependency and is defined as a third approximate expression b3 to be expressed by the following second order polynomial expression (4).

b₃=c₁T²+c₂T+c₃ (4)

All of the coefficients in the coefficients (2), (3), and (4) are measured. First, a frequency temperature characteristic (T-f characteristic) is measured by using pressure P in an operating atmospheric pressure range as a parameter so as to obtain coefficients a₁, a₂, a₃, and a₄ of the expression (2). Next, a pressure frequency characteristic (P-f characteristic) is measured by using a temperature T in the operating temperature range as a parameter so as to obtain coefficients b₄, b₂, and b₃ of the expression (3).

Then, the pressure P is changed by using a temperature Ti as a parameter so as to obtain a resonance frequency, thus obtaining pressure-frequency sensitivity (df/dP)i. The temperature Ti and the pressure-frequency sensitivity (df/dP)i are expressed by curves, and coefficients c₁, c₂, and c₃ of the expression (4) are obtained from the curves.

FIG. 7B is a diagram showing a frequency temperature characteristic of a double-ended tuning fork type quartz crystal vibrating element and a tuning fork type quartz crystal vibrating element under no load. A cutting angle of a quartz crystal substrate is set so as to set a peak temperature of the frequency temperature characteristic at −10° C., for example. When extensional (tensile) stress is applied to the double-ended tuning fork type quartz crystal vibrating element, the peak temperature shifts to a higher temperature side so as to be approximately a normal temperature (25° C.). In this case, an operational range of the tuning fork type quartz crystal vibrating element is a straight line range of the frequency temperature characteristic, whereby the tuning fork type quartz crystal vibrating element is suitable as a temperature sensing element.

When a load is applied to the vibrating element, the shifting amount of the peak temperature of the double-ended tuning fork type quartz crystal vibrating element depends on an amount of the load. Therefore, the peak temperature of the case of no load is set to correspond to a range of a load (stress) generated on the double-ended tuning fork type quartz crystal vibrating element while corresponding to a detecting range of a pressure value of a detected pressure.

### First Embodiment

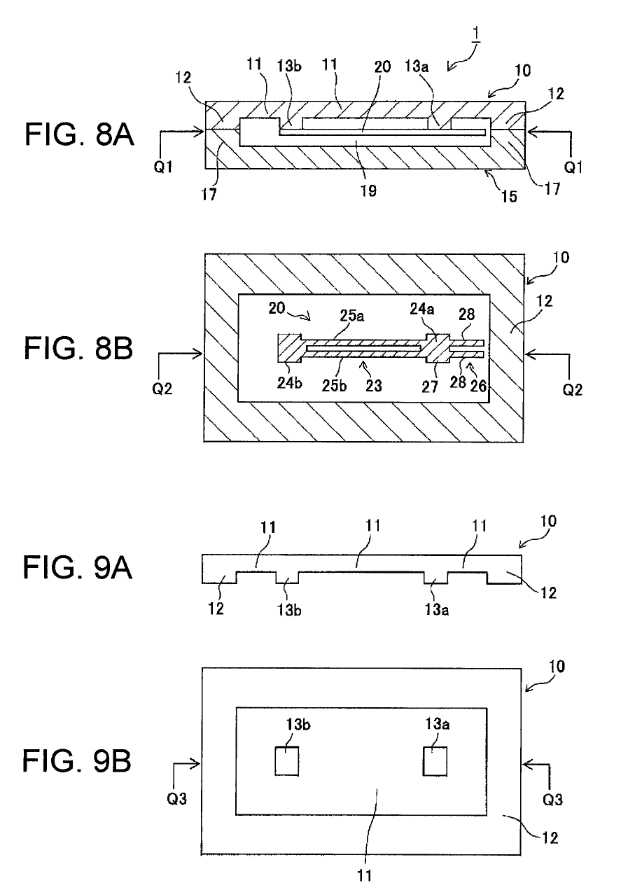

FIGS. 8A and 8B are schematic views showing a structure of a pressure detection unit 1 according to a first embodiment of the present invention. FIG. 8A is a sectional view taken along a Q2-Q2 line of FIG. 8B. FIG. 8B is a sectional view taken along a Q1-Q1 line of FIG. 8A.

This pressure detection unit 1 includes a diaphragm 10 which is deformable under pressure, a base 15 which is provided to face the diaphragm 10 and is not deformable under pressure, and a complex resonator element 20 of which a resonance frequency changes according to deformation of the diaphragm 10.

The complex resonator element 20 includes a first piezoelectric resonator element 23 and a second piezoelectric resonator element 26. The second piezoelectric resonator element 26 is formed to be integrated with a base portion 24a of a pair of base portions 24a and 24b of the first piezoelectric resonator element 23, and resonance frequency of the element 26 changes depending on temperature change.

FIG. 9A is a sectional view showing the diaphragm 10 taken along a Q3-Q3 line of FIG. 9B. FIG. 9B is a plan view of the diaphragm 10 viewed from a lower direction of FIG. 9A.

The diaphragm 10 includes a thin portion 11 which deforms (bends) in response to pressure from an upper direction of FIG. 9A and a frame portion 12 formed at a periphery of the thin portion 11. The diaphragm 10 further includes a pair of supporting portions 13a and 13b for supporting and fixing the base portions 24a and 24b of the complex resonator element 20 on one surface of the thin portion 11.

The first piezoelectric resonator element 23 is supported and fixed at its both base portions 24a and 24b by the supporting portions 13a and 13b. A base portion 27 of the second resonator element 26 is identical with the base portion 24a of the first piezoelectric resonator element 23, so that the second resonator element 26 is also supported and fixed by the supporting portion 13a.

The diaphragm 10 is made of a constant modulus material such as ceramic, glass, and single-crystal which are deformable under pressure. In consideration of an influence of thermal expansion of the diaphragm 10 due to the temperature change, the diaphragm 10 is preferably made of the same material as that of the complex resonator element 20 (the first and second piezoelectric resonator elements 23 and 26), such as a quartz crystal material. The diaphragm 10 can be formed by processing a flat plate made of any of the above materials by a photolithography technique and an etching method used in processing a substrate of a tuning fork type quartz crystal vibrating element.

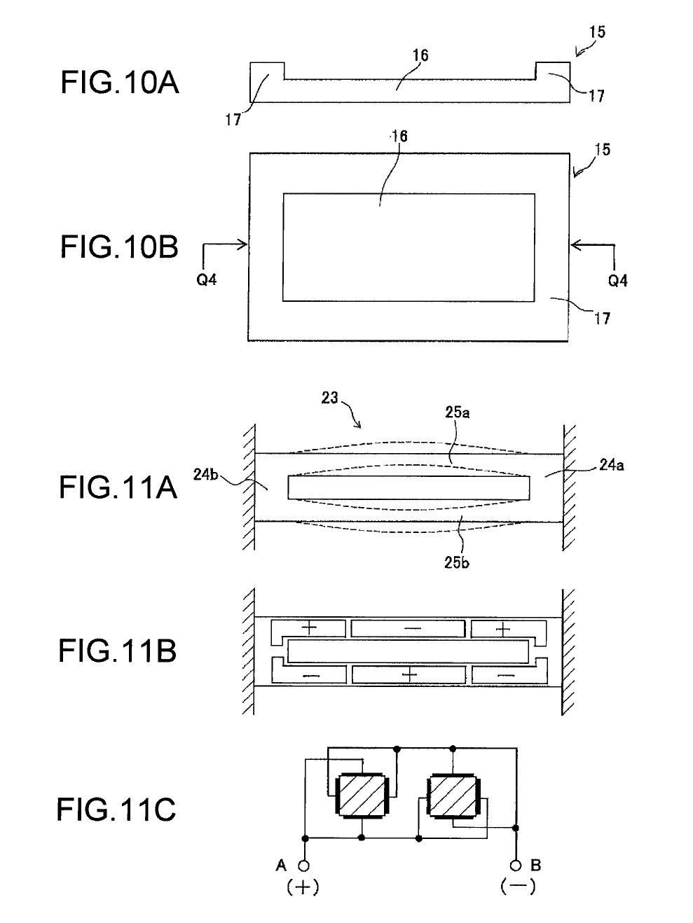

FIG. 10A is a sectional view showing the base 15 taken along a Q4-Q4 line of FIG. 10B. FIG. 10B is a plan view of the base 15.

The base 15 includes a thin portion 16 at its central part, and a frame portion 17 formed at a periphery of the thin portion 16.

The thin portion 16 of the base 15 is made of an insulation material such as ceramic, glass, and single crystal and formed to have a thickness at an extent that the portion 16 does not deform by pressure applied to the diaphragm 10.

The frame portion 17 of the base 15 is bonded to the frame portion 12 of the diaphragm 10 with a bonding material. Therefore, in consideration of an influence of thermal expansion of the base 15 due to the temperature change, the base 15 is preferably made of the same material as that of the diaphragm 10, such as a crystal material. The base 15 is formed by the same processing method as that of the diaphragm 10.

The first piezoelectric resonator element 23 of the complex resonator element 20 shown in FIG. 8 is a double-ended tuning fork type piezoelectric vibrating element including a pair of resonating arms 25a and 25b and the base portions 24a and 24b respectively integrated with both ends of the pair of resonating arms 25a and 25b. Hereinafter, the first piezoelectric resonator element 23 is referred to also as a double-ended tuning fork type piezoelectric vibrating element 23 or a double-ended tuning fork type quartz crystal vibrating element 23. The second piezoelectric resonator element 26 of the complex resonator element 20 is a tuning fork type piezoelectric vibrating element having a pair of resonating arms 28 and the base portion 27 integrated with one ends of the resonating arms 28. Hereinafter, the second piezoelectric resonator element 26 is referred to as also a tuning fork type piezoelectric vibrating element 26 or a tuning fork type quartz crystal vibrating element 26. The base portion 27 is identical with the base portion 24a of the first piezoelectric resonator element 23. Though the base portion 27 and the base portion 24a are identical, two reference numbers are provided to the identical element for the sake of understanding.

Vibration energy of the resonating arms 25a and 25b of the double-ended tuning fork type piezoelectric vibrating element 23 is substantially decreased at the base portions 24a and 24b. Therefore, even though the base portions 24a and 24b are supported and fixed, an influence, such as increase of a crystal impedance (CI) value (a resistance value of an electrical equivalent circuit), on vibration of the vibrating element 23 is extremely small.

Further, vibration energy of the resonating arms 28 of the tuning fork type piezoelectric vibrating element 26 is substantially decreased at the base portion 27. Therefore, even though the base portion 27 is supported and fixed, an influence on vibration of the vibrating element 26 is extremely small. Accordingly, the complex resonator element 20 in which the base portion 27 of the tuning fork type piezoelectric vibrating element 26 and the base portion 24a of the double-ended tuning fork type piezoelectric vibrating element 23 are formed in an identical manner is a complex type piezoelectric element shown in FIG. 8B.

An example that a double-ended tuning fork type quartz crystal vibrating element is used as the first piezoelectric resonator element 23 is described.

The double-ended tuning fork type quartz crystal vibrating element 23 includes the pair of base portions 24a and 24b; the resonating arms (stress sensing portions) 25a and 25b composed of a piezoelectric substrate having two vibration beams connecting between the base portions 24a and 24b; and an excitation electrode formed on a vibration area of the piezoelectric substrate, as shown in FIG. 11A.

FIG. 11A is a plan view showing a vibrating mode of the double-ended tuning fork type quartz crystal vibrating element 23. The excitation electrode is disposed so as to vibrate the vibration beams of the vibrating element 23 symmetrically to a central axis in a longitudinal direction (vibration beams). FIG. 11B is a plan view showing an excitation electrode formed on the vibrating element 23 and signs of electric charges, which are excited at a certain moment, on the excitation electrode. FIG. 11C is a schematic sectional view showing a wire connection of the excitation electrode.

A double-ended tuning fork type quartz crystal vibrating element has excellent sensitivity with respect to extensional stress and compressive stress. Further, the vibrating element exhibits excellent resolution ability when used as a stress sensing element of an altimeter or a depth finder, being able to obtain altitude difference and depth difference from slight difference of atmospheric pressure.

A frequency temperature characteristic of a double-ended tuning fork type quartz crystal vibrating element is expressed by an upward protrusive quadratic curve and a peak temperature thereof depends on a rotation angle about an X axis (an electric axis of quartz crystal). Each parameter is commonly set so as to make the peak temperature be a normal temperature (25° C.).

A resonance frequency f_{F} when external force F is applied to two vibration beams of the double-ended tuning fork type quartz crystal vibrating element is expressed as follows.

f_{F}=f₀(1−(KL²F)/(2EI))^{1/2} (5)

Here, f₀ denotes a resonance frequency of the double-ended tuning fork type quartz crystal vibrating element to which no external force is applied, K denotes a constant (=0.0458) in a fundamental mode, L denotes a length of the vibration beam, E denotes a longitudinal elastic constant, and I denotes a second moment of area. The second moment of area I is expressed as I=dw³/12, so that the expression (5) can be transformed as the following expression. Here, d denotes a thickness of the vibration beam and w denotes a width of the same.

f_{F}=f₀(1−S_{Fσ})^{1/2} (6)

Here, stress sensitivity S_{F} and stress σ are respectively expressed as Expression (7) and Expression (8).

S_{F}=12(K/E)(L/w)² (7)

σ=F/(2A) (8)

Here, A denotes a sectional area (=w·d) of the vibration beam.

From the above, force F acting on the double-ended tuning fork type vibrating element in a compressive direction is set to be negative and the force F acting on the vibrating element in an extensional direction (tensile direction) is set to be positive. In the relationship between the force F and the resonance frequency f_{F}, the resonance frequency f_{F} decreases when the force F is compressive force, and the resonance frequency f_{F} increases when the force F is extensional (tensile) force. The stress sensitivity S_{F} is proportional to the square of L/w of the vibration beam.

Here, a stress sensing element is not limited to the double-ended tuning fork type quartz crystal vibrating element, but any piezoelectric vibrating element can be used as long as the vibrating element has a frequency temperature characteristic which is expressed by an upward protrusive quadratic curve and has a frequency and a peak temperature which shift depending on extensional stress and compressive stress.

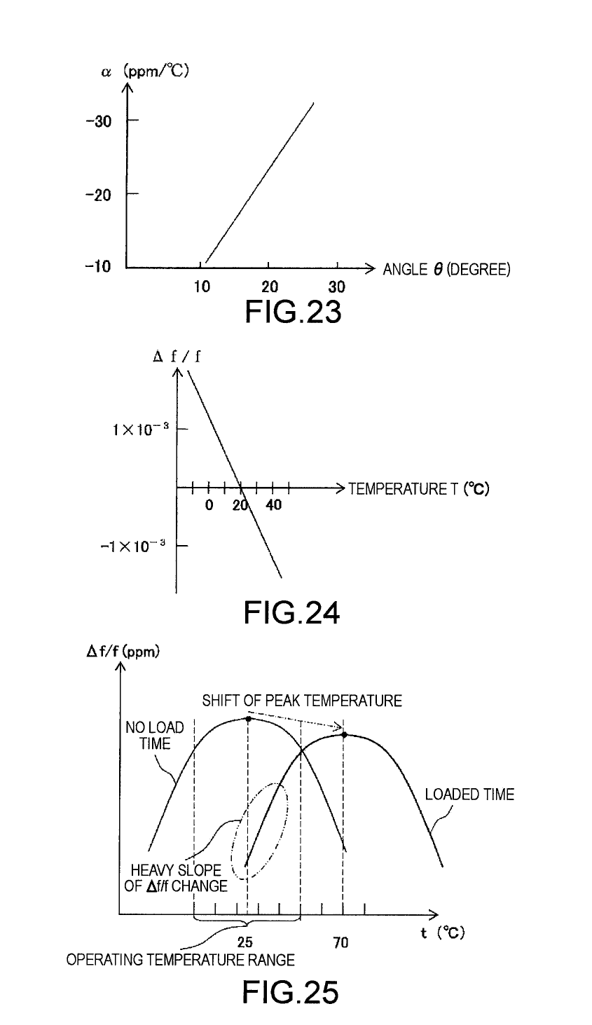

As the second piezoelectric resonator element 26 serving as a temperature sensing element (a temperature sensor), the tuning fork type piezoelectric vibrating element having the pair of resonating arms 28 and the base portion 27 (24a) integrated with one end parts of the resonating arms 28 is used. For example, a turning fork type quartz crystal vibrating element obtained by θ-rotating a quartz crystal Z-cut plate about X axis (electric axis of quartz crystal) as shown in FIG. 22 is used. A frequency temperature characteristic of a common tuning fork type quartz crystal resonator is expressed by an upward protrusive quadratic curve and a peak temperature is set to be a normal temperature. However, according to U.S. Pat. No. 3,010,922, a rotation angle θ about X axis and first order coefficient α of the frequency temperature characteristic have a relationship therebetween shown in FIG. 23. FIG. 24 shows a frequency temperature characteristic of a tuning fork type quartz crystal resonator for temperature detection. As shown in FIG. 24, frequency change Δf/f with respect to a temperature T is expressed by a nearly straight line.

The complex resonator element 20 can be formed by processing a quartz crystal Z plate by a photolithography technique and an etching method used in processing a substrate process of a tuning fork type crystal resonator and in forming an electrode.

A shape and a dimension of a double-ended tuning fork type quartz crystal vibrating element are set so as to obtain a desired resonance frequency. As known, a peak temperature of the frequency temperature characteristic of the double-ended tuning fork type quartz crystal vibrating element depends on a rotation angle about X axis (electric axis of quartz crystal). Further, according to the above-mentioned viewpoint of the inventor, the peak temperature also depends on stress applied to the double-ended tuning fork type quartz crystal vibrating element. The peak temperature shifts to a higher temperature side when extensional (tensile) stress is applied to the double-ended tuning fork type quartz crystal vibrating element, and the peak temperature shifts to a lower temperature side when compressive stress is applied. Therefore, a cutting angle (an angle about X axis) of a substrate is determined in consideration of a range of pressure which is measured by a pressure detection unit and a range of an operating temperature, in order for the double-ended tuning fork type quartz crystal vibrating element to suitably operate.

For example, an operating temperature range of the pressure detection unit is set to be from 0° C. to 50° C. (a central temperature is 25° C.). A peak temperature Tc1 of the first piezoelectric resonator element (double-ended tuning fork type quartz crystal vibrating element) 23 is preferably set to be 25° C. in a stress applying (1 atmosphere) state. When extensional (tensile) stress at 1 atmosphere is applied to the double-ended tuning fork type quartz crystal vibrating element, the peak temperature Tc1 shifts to a higher temperature side by about 31° C. In order to set the peak temperature Tc1 of the vibrating element 23 to be 25° C. in the 1 atmosphere applying state, the temperature Tc1 needs to be set to be about −10° C. in a no stress applying state. Therefore, an angle θ of the substrate of the complex resonator element 20 is set in order for the peak temperature Tc1 to be about −10° C. A peak temperature Tc2 of the second piezoelectric resonator element 26 is also about −10° C. Since the frequency temperature characteristic of the second piezoelectric resonator element 26 is expressed by an upward protrusive quadratic curve, a temperature of the pressure detection unit is measured by using a temperature-frequency curve at the higher temperature side than the peak temperature Tc2. An operating temperature range of the second piezoelectric resonator element 26 is set to be higher than the peak temperature Tc2. In the above example, the operating temperature is set to be in the range from 0° C. to 50° C. which is higher than the peak temperature Tc2=−10° C.

An adhesive is applied to the pair of supporting portions 13a and 13b formed on one surface of the thin portion 11 of the diaphragm 10 shown in FIG. 9 and the base portions 24a and 24b of the complex resonator element 20 are placed on the adhesive so as to harden the adhesive and fix the base portions 24a and 24b on the supporting portions 13a and 13b. Then an adhesive is applied to the frame portion 17 of the base 15 shown in FIG. 10 and the frame portions 12 and 17 are bonded to each other in vacuum in a manner adjusting their circumferences, so as to be hardened. Accordingly, an inside 19 of the pressure detection unit 1 is vacuumed, being able to decrease CI values (increase a Q value) of the first piezoelectric resonator element 23 and the second piezoelectric resonator element 26 constituting the complex resonator element 20.

A lead electrode extending from an excitation electrode of each of the first piezoelectric resonator element 23 and the second piezoelectric resonator element 26 is extracted to the outside through a part of the frame 12 of the diaphragm 10 or a part of the frame 17 of the base 15.

In a method for vacuuming the inside 19 of the pressure detection unit 1, after the diaphragm 10 and the base 15, one of which has a small hole formed on a part thereof, are bonded to each other, the inside 19 may be vacuumed through the small hole and then the small hole may be closed.

It is not preferable to use an organic adhesive such as epoxy of which stress relaxation is large for bonding the pair of supporting portions 13a and 13b of the diaphragm 10 and the base portions 24a and 24b of the complex resonator element 20.

An operation of the pressure detection unit 1 will be described. Since the inside 19 of the pressure detection unit 1 is vacuumed, 1 atmosphere (reference pressure) is applied to an outer surface of the diaphragm 10 at a normal temperature and therefore the thin portion 11 bends toward the inside. Because of the bend of the thin portion 11, the pair of supporting portions 13a and 13b formed on the thin portion 11 turns to outer directions, that is, the supporting portion 13a turns to a right direction (outer direction) in FIG. 8A and the supporting portion 13b turns to a left direction (outer direction). As a result, extensional (tensile) stress is applied on the first piezoelectric resonator element 23 of the complex resonator element 20. However, stress due to the bend of the thin portion 11 of the diaphragm 10 is not applied to the second piezoelectric resonator element 26 continuously formed to the base portion 24a (27) of the complex resonator element 20.

An object for measuring absolute pressure is gas, liquid, or the like. Here, a case of liquid will be described as an example. When the pressure detection unit 1 is placed in measured liquid in a case where measured pressure is higher than a reference pressure, the thin portion 11 of the diaphragm 10 bends to a more inside direction than in a case of the reference pressure, whereby the resonance frequency of the first piezoelectric resonator element 23 changes from the frequency at the reference pressure. In a case where the measured presser is lower than the reference pressure, a bending amount of the thin portion 11 of the diaphragm 10 is decreased, whereby the resonance frequency of the first piezoelectric resonator element 23 changes from the frequency of the reference pressure.

Stress applied to the first piezoelectric resonator element 23 can be obtained by measuring frequency difference between the frequency in the case of the reference pressure and the frequency in the case where the unit is in the measured liquid. Based on the obtained stress, absolute pressure applied on the pressure detection unit 1 can be obtained.

The resonance frequency of the first piezoelectric resonator element 23 changes depending on a temperature of the measured liquid. Therefore, a temperature T0 of the pressure detection unit in measuring the reference pressure and a temperature T1 of the pressure detection unit disposed in the measured liquid are measured by using the second piezoelectric resonator element 26 of the complex resonator element 20 as a temperature sensing element (temperature sensor). Temperature difference ΔT (=T1−T0) is obtained so as to correct the frequency, which is measured, of the first piezoelectric resonator element 23. That is, an amount of a frequency change of the first piezoelectric resonator element 23 due to the temperature difference ΔT is corrected according to a measured frequency changing amount, so as to obtain only an amount of frequency change due to difference between the reference pressure and the pressure of the measured liquid. Thus, stress applied to the first piezoelectric resonator element 23 is obtained by excluding an influence of the temperature change, and pressure applied to the diaphragm 10 is obtained based on the obtained stress.

The base portion of the first piezoelectric resonator element and the base portion of the second piezoelectric resonator element are identical as described above, being able to downsize the pressure detection unit. Further, the second piezoelectric resonator element detecting a temperature is formed to contact with the first piezoelectric resonator element detecting pressure (stress), so as to be able to precisely detect the temperature of the first piezoelectric resonator element as a digital quantity. Therefore, the frequency change due to the temperature change of the first piezoelectric resonator element can be corrected so as to substantially improve accuracy of measuring pressure of a measured medium. Further, power consumption can be substantially reduced as described later compared to an analog temperature-detecting method.

The pressure detection unit using a double-ended tuning fork type piezoelectric vibrating element for pressure detection is substantially superior to a pressure (stress) detection unit having pressure (stress) detecting sensitivity in other vibration modes such as thickness-sliding vibration, longitudinal vibration, and surface acoustic wave vibration. Thus, a pressure detection unit of high sensitivity can be structured.

Further, accuracy in temperature detection is substantially improved by using the tuning fork type piezoelectric vibrating element for detecting the temperature of the stress detection unit. Furthermore, power consumption for the temperature detection can be extremely reduced. The peak temperature of the frequency temperature characteristic can be set within an operating temperature range by appropriately adjusting the cutting angle of the first piezoelectric resonator element, being able to improve detecting accuracy of the pressure detection unit even through the temperature changes.

### Second Embodiment

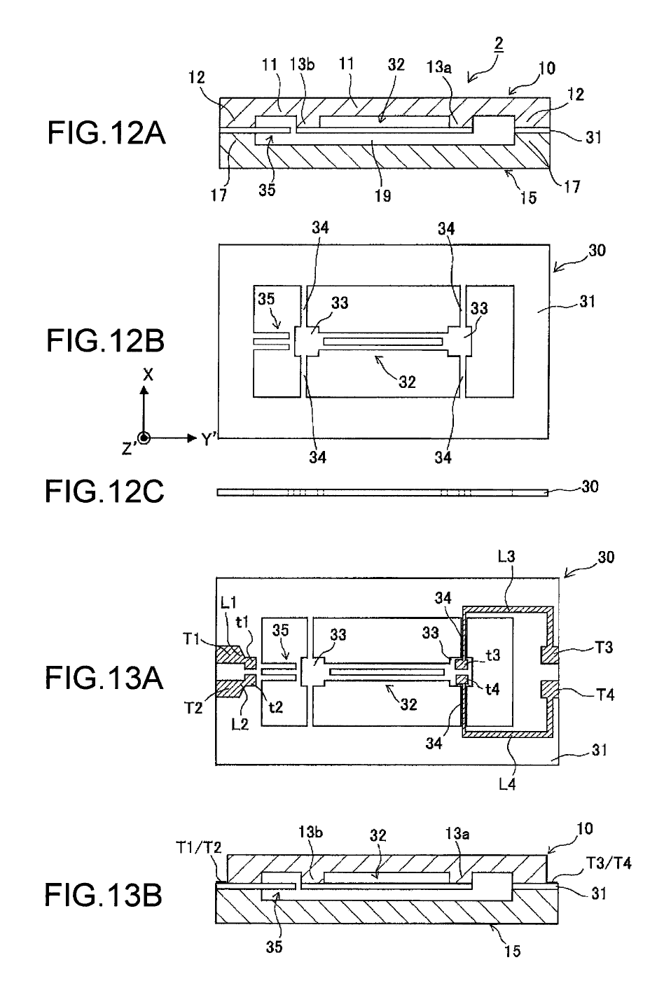

FIGS. 12A to 12C are diagrams showing a structure of a pressure detection unit 2 according to a second embodiment. FIG. 12A is a sectional view of the pressure detection unit 2, FIG. 12B is a plan view of a framed piezoelectric resonator element 30, and FIG. 12C is a lateral view of FIG. 12B. The pressure detection unit 2 includes: the diaphragm 10, the base 15, and the framed piezoelectric resonator element 30. The diaphragm 10 is deformable by pressure. The base 15 is formed to face the diaphragm 10 and is not deformable by pressure. The framed piezoelectric resonator element 30 includes a first piezoelectric resonator element 32 of which a resonance frequency changes in response to deformation of the diaphragm 10 and a second piezoelectric resonator element 35 of which a resonance frequency changes in response to temperature change.

The diaphragm 10 and the base 15 have the same structures as those of the diaphragm 10 and the base 15 of the pressure detection unit 1 of the first embodiment.

The framed piezoelectric resonator element 30 includes an outer frame 31 having a rectangular shape, the first piezoelectric resonator element (double-ended tuning fork type quartz crystal vibrating element) 32, supporting pieces 34 supporting base portions 33 of the first piezoelectric resonator element 32, and the second piezoelectric resonator element (tuning fork type quartz crystal vibrating element) 35.

The framed piezoelectric resonator element 30 has such a structure that each of the base portions 33 of the first piezoelectric resonator element 32 is coupled with an inside of the outer frame 31 by two supporting pieces 34 in an integrated manner and a pair of resonating arms of the second piezoelectric resonator element 35 is connected with the inside of the outer frame 31. Here, the outer frame 31, the first piezoelectric resonator element 32, the supporting pieces 34, and the second piezoelectric resonator element 35 are formed on the same level.

The framed piezoelectric resonator element 30 can be formed by processing a quartz crystal Z plate by a photolithography technique and an etching method used in manufacturing a tuning fork type crystal resonator.

In order to structure the pressure detection unit 2, an adhesive is first applied to the frame portion 12, the pair of supporting portions 13a and 13b formed on the thin portion 11 of the diaphragm 10, and an upper surface of the frame portion 17 of the base 15. Then the diaphragm 10, the framed piezoelectric resonator element 30, and the base 15 are layered in this order in a manner to adjust their circumferences to each other.

An operation of the pressure detection unit 2 is same as that of the pressure detection unit 1 shown in FIGS. 8A and 8B, so that the description thereof is omitted.

A different point of the pressure detection unit 2 from the pressure detection unit 1 shown in FIGS. 8A and 8B is that the first piezoelectric resonator element 32 is provided apart from the second piezoelectric resonator element 35. Therefore, acoustic bond between the elements 32 and 35 is extremely small, resulting in no degradation of pressure detection accuracy caused by mutual acoustic interference.

FIG. 13A is a plan view showing an example of a lead electrode (extracted electrode) extended from the double-ended tuning fork type quartz crystal vibrating element 32 and the tuning fork type quartz crystal vibrating element 35 formed on the framed piezoelectric resonator element 30.

Descriptions of excitation electrodes of the double-ended tuning fork type quartz crystal vibrating element 32 and the tuning fork type quartz crystal vibrating element 35 are omitted because they are known. Lead electrodes L3 and L4 are respectively extended from electrode terminals t3 and t4 of the double-ended tuning fork type quartz crystal vibrating element 32 through the supporting pieces 34 and the outer frame 31 to terminal electrodes T3 and T4 which are provided at an end portion of the outer frame 31. In addition, lead electrodes L1 and L2 are respectively extended from electrode terminals t1 and t2 of the tuning fork type quartz crystal vibrating element 35 to terminal electrodes T1 and T2 which are provided at another end portion of the outer frame 31. Thus the lead electrodes L1, L2, L3, and L4 and the terminal electrodes T1, T2, T3, and T4 are provided to the resonator element 30, being able to excite the tuning fork type quartz crystal vibrating element 35 and the double-ended tuning fork type quartz crystal vibrating element 32 through the terminal electrodes T1, T2, T3, and T4.

FIG. 13B shows an example of the pressure detection unit 2 of which the diaphragm 10 is shorter than the base 15 and the framed piezoelectric resonator element 30 in a longitudinal direction (beam direction of the double-ended tuning fork type quartz crystal vibrating element 32). The terminal electrodes T1, T2, T3, and T4 provided at the end portions of the outer frame 31 of the framed piezoelectric resonator element 30 are exposed on an outer surface of the pressure detection unit 2 so as to be easily connected with external electric circuits.

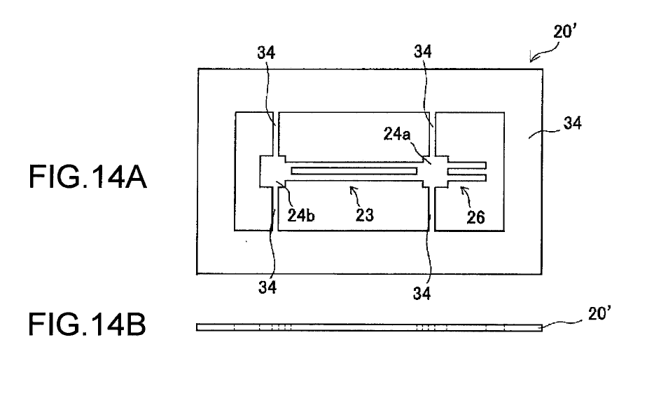

The pressure detection unit 1 shown in FIGS. 8A and 8B is structured by bonding the complex resonator element 20, which is formed by the photolithography technique, to the supporting portions 13a and 13b of the diaphragm 10. However, a framed piezoelectric resonator element 20′ shown in a plan view of FIG. 14A and a lateral view of FIG. 14B may be formed so as to structure a pressure detection unit 1′ in a similar manner to the pressure detection unit 2 shown in FIGS. 12A to 12C. The process technology can be utilized in such the structure, being able to achieve low cost and stable quality.

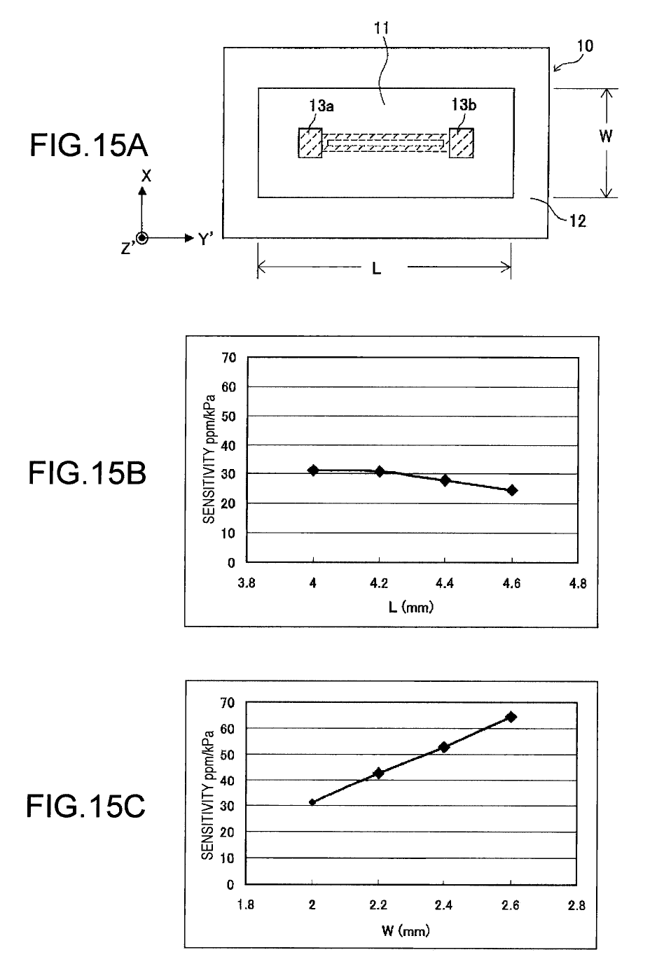

FIG. 15A is a plan view showing the diaphragm 10 viewed from an inside. In the drawing, L denotes a dimension of the thin portion 11 in Y′ axis direction and W denotes a dimension of the same in X axis direction. Relationships between the dimension L and stress sensitivity and between the dimension W and stress sensitivity when constant pressure was applied to an outer surface of the diaphragm 10 were obtained by simulations. FIG. 15B shows a curve which shows a relationship between the dimension L and stress sensitivity when the dimension W in the X axis direction is set to be constant (W=2.0 mm) and the dimension L in the Y′ axis direction is changed from 4.0 mm to 4.6 mm. FIG. 15C shows a curve which shows a relationship between the dimension W and stress sensitivity when the dimension L in the Y′ axis direction is set to be constant (L=4.0 mm) and the dimension W in the X axis direction is changed from 2.0 mm to 2.6 mm. FIG. 15B shows that even though the dimension L in the Y′ axis direction is increased, the stress sensitivity is degraded. However, FIG. 15C shows that as the dimension W in the X axis direction is increased, the stress sensitivity is increased.

### Third Embodiment

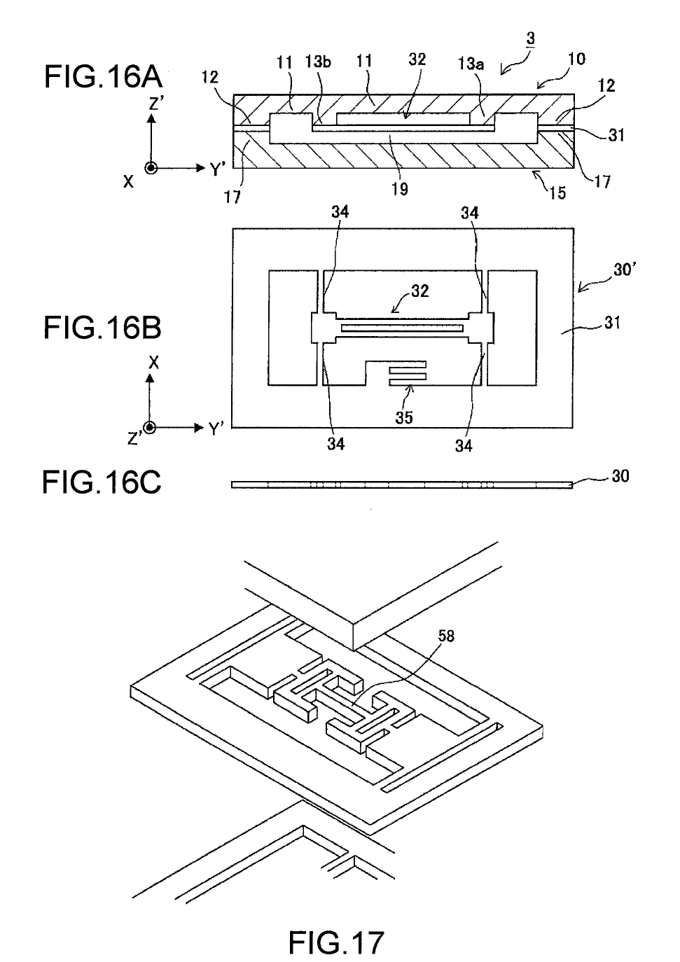

FIGS. 16A to 16C are diagrams showing a structure of a pressure detection unit 3 according to a third embodiment. FIG. 16A is a sectional view of the pressure detection unit 3, FIG. 16B is a plan view of a framed piezoelectric resonator element 30′, and FIG. 16C is a lateral view of FIG. 16B.

According to the simulation result of the relationship between shape/dimension of the thin portion 11 and the stress sensitivity of the same shown in FIGS. 15B and 15C, it was proved that increase of the dimension, in the X axis direction, of a pressure detection unit was effective in increasing the stress sensitivity. FIG. 16B shows a structure in which the second piezoelectric resonator element (tuning fork type quartz crystal vibrating element) 35 is connected with the outer frame 31 in the X axis direction. On the other hand, in the framed piezoelectric resonator element 30 shown in FIG. 12B, the second piezoelectric resonator element 35 is provided so as to be connected with the outer frame 31 in the Y′ axis direction. Thus the dimension in the Y′ axis direction is large in the resonator element 30, whereby an effect for improving the stress sensitivity is small.

An operation of the pressure detection unit 3 is same as that of the pressure detection unit 1 shown in FIGS. 8A and 8B, so that the description thereof is omitted.

The pressure detection unit 3 exhibits pressure detecting accuracy with no deterioration caused by internal acoustic interference between the first piezoelectric resonator element 32 and the second piezoelectric resonator element 35. Further, the pressure detection unit 3 has a larger dimension in the X axis direction than the pressure detection units 1 and 2, so that the stress sensitivity is improved compared to the units 1 and 2.

Further, the pressure detection unit 3 is structured such that the first and second piezoelectric resonator elements are formed to be connected with one outer frame. Therefore, the unit can be formed by a process proceeding using a large sized wafer, achieving downsizing and cost reduction of the detection unit. Furthermore, the pressure detection unit 3 is fabricated such that the frame portion 12 of the diaphragm 10, the frame portion 17 of the base 15, and the outer frame 31 which couples the first and second piezoelectric resonator elements 32 and 35 are adjusted to each other. Thus fabricating accuracy is improved and the fabrication becomes easy. Further, since the temperature of the first piezoelectric resonator element can be precisely detected as a digital quantity, an error, caused by the temperature change, of stress detected by the first piezoelectric resonator element can be corrected. Thus, pressure measurement accuracy is substantially improved. In addition, this is substantially effective to reduction of power consumption.

Adhesives are used for bonding the diaphragm 10 and the base 15 in the pressure detection unit 1, bonding the diaphragm 10, the framed piezoelectric resonator element 30, and the base 15 in the pressure detection unit 2, and bonding the diaphragm 10, the framed piezoelectric resonator element 30′, and the base 15 in the pressure detection unit 3. However, the bonding is not performed only by using the adhesives, but the bonding may be performed by using an organic bonding material such as low melting glass, or may be direct bonding.

In the above embodiments and modifications, the double-ended tuning fork type quartz crystal vibrating element is used as the pressure sensing element of the pressure sensor, but a pressure sensing element shown in FIG. 17 may be used.

FIG. 17 is a development perspective view schematically showing a structure of another pressure sensor. The same elements as those of the above embodiments are given the same reference numerals as the above and the descriptions thereof are not repeated. Different points from the above embodiments will be mainly described. In the pressure sensor shown in FIG. 17, a vibrating element composed of a column shaped beam 58 (also called a single beam) having one resonator element serving as a pressure sensing part is formed as a pressure sensing element on a pressure sensing element layer.

Accordingly, the pressure sensor can detect pressure from the outside in accordance with resonance frequency change, occurring in response to pressure change, of the vibrating element, as is the case with the pressure sensors of the above embodiments.

A peak temperature of a frequency temperature characteristic can be set within an operating temperature range in an operating state by appropriately adjusting a cutting angle of the vibrating element, being able to improve detecting accuracy of the pressure detection unit even though the temperature changes.

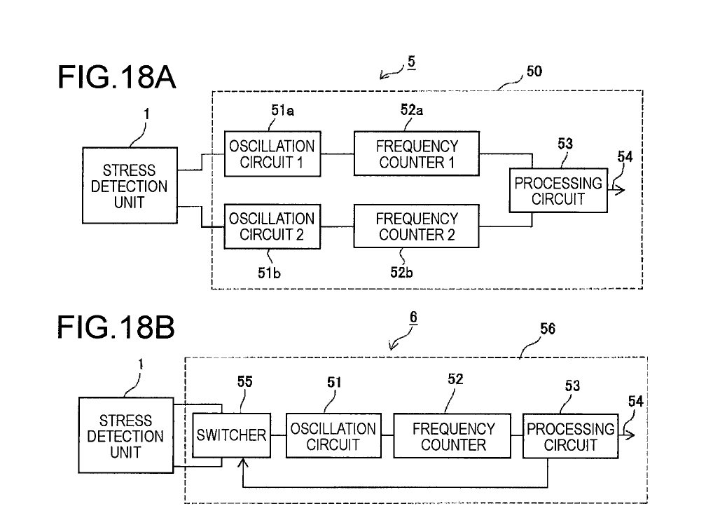

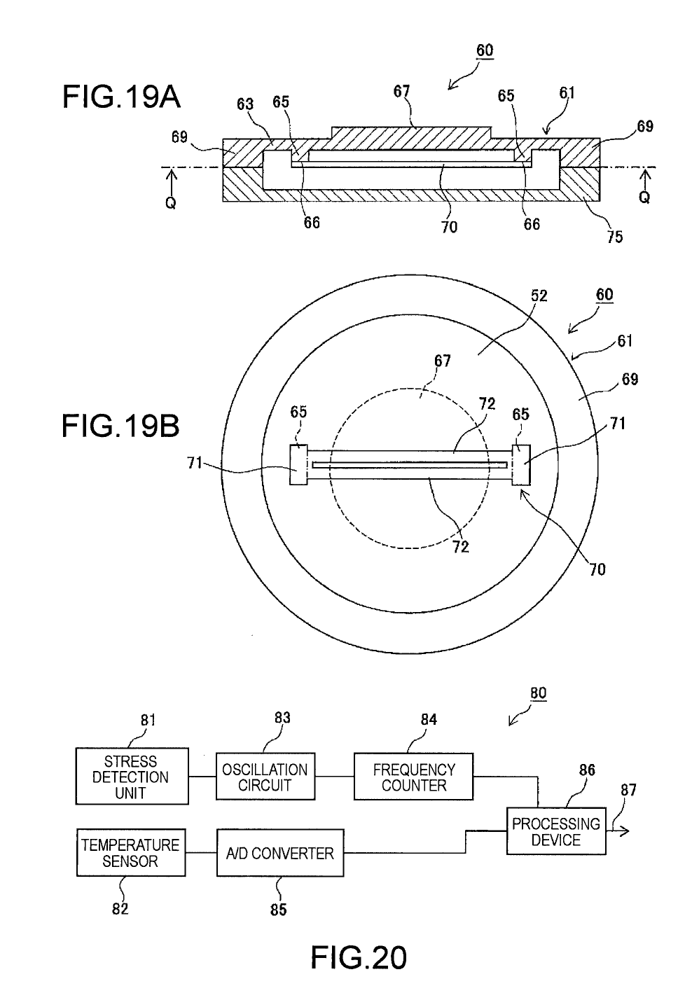

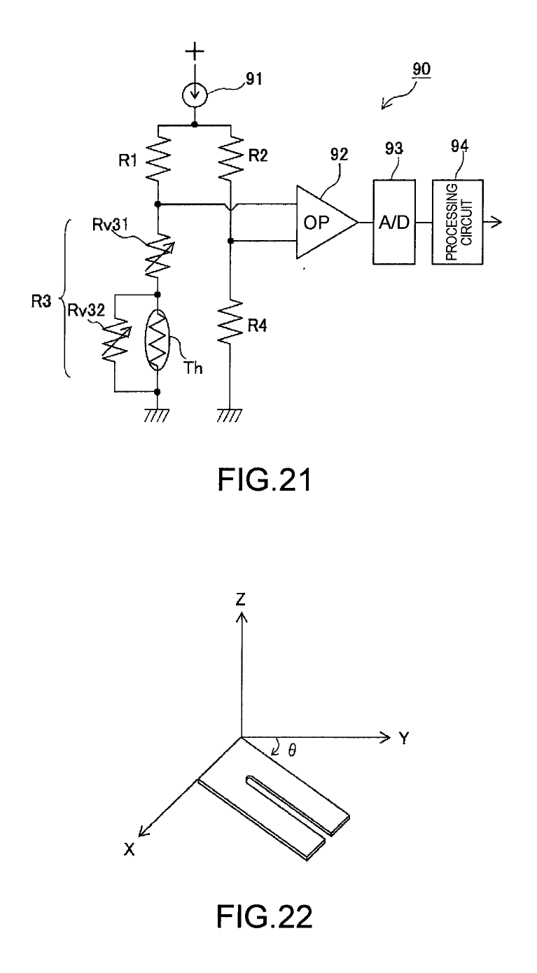

FIG. 18A is a block diagram showing a structure of a stress sensor.

This stress sensor 5 is composed of the stress detection unit 1 (2, 3) and a stress detection circuit 50. The stress detection unit 1 (2, 3) have been described above, so that a detailed description thereof is not repeated. The stress detection circuit 50 includes first and second oscillation circuits 51a and 51b, first and second frequency counters 52a and 52b, and a processing circuit 53.

The first oscillation circuit 51a operates the first piezoelectric resonator element 23 (32) of the stress detection unit 1. The second oscillation circuit 51b operates the second piezoelectric resonator element 26 (35). The first frequency counter 52a counts frequency of a stress detection signal outputted from the first oscillation circuit 51a. The second frequency counter 52b counts frequency of a temperature detection signal outputted from the second oscillation circuit 51b. The processing circuit 53 calculates a frequency count signal outputted from the second frequency counter 52b so as to detect a temperature, and corrects a frequency count signal outputted from the first frequency counter 52a based on the temperature detection result. Further, the processing circuit 53 calculates the corrected signal to obtain stress.

In the stress sensor 5 structured as above, current consumption of the oscillation circuit is 20 μA, and current consumption of an asynchronous frequency counter of 20 NHz and 24 bit is 20 μA. Here, the current consumption of the stress sensor 5 is one tenth of that in an analog temperature detecting method, thus being able to substantially reduce the current consumption.

Further, the pressure sensor is composed of the pressure detection unit 1 (2, 3) described above and the stress detection circuit 50 including the oscillation circuits, the frequency counters, and the like, so that a downsized pressure sensor can be realized. Further, pressure measurement accuracy of the sensor can be improved due to the temperature correction, and current consumption can be substantially reduced.

FIG. 18B is a block diagram showing another structure of a stress sensor.

This stress sensor 6 shown in FIG. 18B is composed of the stress detection unit 1 (2, 3) and a stress detection circuit 56. The stress detection circuit 56 includes an oscillation circuit 51, a frequency counter 52, the processing circuit 53, and a switcher 55.

The oscillation circuit 51 operates the first piezoelectric resonator element 23 (32) or the second piezoelectric resonator element 26 (35), which is coupled to the circuit 51 through the switcher 55, of the stress detection unit 1 (2, 3). The frequency counter 52 counts frequency of a stress detection signal or frequency of a temperature detection signal outputted from the oscillation circuit 51. The processing circuit 53 controls the switcher 55 in a time-division manner, calculates a frequency count signal outputted from the frequency counter 52 in the time-division manner so as to detect a temperature and correct the frequency count signal outputted from the frequency counter 52 in the time-division manner based on the temperature detection result. Further, the processing circuit 53 calculates the corrected signal to obtain stress.

In the stress sensor 6 structured as above, the oscillation circuit 51 is coupled to the stress detection unit 1 through the switcher 55, thus being able to reduce one oscillation circuit and one frequency counter compared to the stress sensor 5 shown in FIG. 18A.

Accordingly, a downsized pressure detection unit can be achieved and current consumption can be reduced while maintaining the pressure measuring accuracy which is equivalent to that of the pressure sensor shown in FIG. 18A.

The entire disclosure of Japanese Patent Application No. 2009-015057, filed Jan. 27, 2009 and Japanese Patent Application No. 2009-255785, filed Nov. 9, 2009 is expressly incorporated by reference herein.

1. A pressure detection unit, comprising:
a first piezoelectric resonator element having a vibrating portion and a pair of base portions connected to both ends of the vibrating portion;
a second piezoelectric resonator element having a resonating arm and a base portion integrated with one end of the resonating arm;
a diaphragm having a pair of supporting portions to which the base portions of the first piezoelectric resonator element are bonded; and
a base disposed to be opposed to the diaphragm, wherein
the base portion of the second piezoelectric resonator element is joined to one of the base portions of the first piezoelectric resonator element in an identical plane.

2. A pressure detection unit, comprising:
a first piezoelectric resonator element layer including a first piezoelectric resonator element having a vibrating portion and a pair of base portions connected to both ends of the vibrating portion, a frame portion surrounding the first piezoelectric resonator element, and a supporting piece connecting the frame portion and each of the base portions;
a second piezoelectric resonator element having a resonating arm and a base portion integrated with one end of the resonating arm;
a diaphragm layer including a pair of supporting portions that cover one main surface of the first piezoelectric resonator element layer and are respectively bonded to the base portions of the first piezoelectric resonator element; and
a base layer covering the other main surface of the first piezoelectric resonator element layer, wherein
the base portion of the second piezoelectric resonator element is joined to a side of the frame portion, and the second piezoelectric resonator element and the first piezoelectric resonator element are disposed on the same level.

3. The pressure detection unit according to claim 1, wherein
the first piezoelectric resonator element has a frequency temperature characteristic that is expressed by an upward protrusive quadratic curve, and
a cutting angle of the first piezoelectric resonator element is set so that a peak temperature of the frequency temperature characteristic is in an operating temperature range when a load is applied.

4. The pressure detection unit according to claim 1, wherein the vibrating portion is composed of at least one column beam.

5. The pressure detection unit according to claim 1, wherein the second piezoelectric resonator element is a tuning fork type vibrating element.

6. A pressure detection unit, comprising:
a piezoelectric resonator element having a vibrating portion and a pair of base portions connected to both ends of the vibrating portion;
a diaphragm having a pair of supporting portions to which the base portions of the piezoelectric resonator element are bonded; and
a base disposed to be opposed to the diaphragm, wherein
the piezoelectric resonator element has a frequency temperature characteristic that is expressed by an upward protrusive quadratic curve, and
a cutting angle of the piezoelectric resonator element is set so that a peak temperature of the frequency temperature characteristic is in an operating temperature range when a load is applied.

7. A pressure sensor, comprising:
the pressure detection unit according to claim 1; and
a stress detection circuit, wherein
the stress detection circuit includes: a first oscillation circuit operating the first piezoelectric resonator element of the pressure detection unit, a second oscillation circuit operating the second piezoelectric resonator element, a first frequency counter counting frequency of a stress detection signal outputted from the first oscillation circuit, a second frequency counter counting frequency of a temperature detection signal outputted from the second oscillation circuit, and a processing circuit correcting a frequency count signal outputted from the first frequency counter by a frequency count signal outputted from the second frequency counter.

8. A pressure sensor, comprising:
the pressure detection unit according to claim 1; and
a stress detection circuit, wherein
the stress detection circuit includes: an oscillation circuit operating one of the first and second piezoelectric resonator elements through a switcher, a frequency counter counting frequency of an output signal of one of the first and second piezoelectric resonators outputted from the oscillation circuit, and a processing circuit correcting a frequency count signal outputted from the frequency counter.

9. The pressure detection unit according to claim 2, wherein
the first piezoelectric resonator element has a frequency temperature characteristic that is expressed by an upward protrusive quadratic curve, and
a cutting angle of the first piezoelectric resonator element is set so that a peak temperature of the frequency temperature characteristic is in an operating temperature range when a load is applied.

10. The pressure detection unit according to claim 2, wherein the vibrating portion is composed of at least one column beam.

11. The pressure detection unit according to claim 2, wherein the second piezoelectric resonator element is a tuning fork type vibrating element.

12. A pressure sensor, comprising:
the pressure detection unit according to claim 1; and
a stress detection circuit, wherein
the stress detection circuit includes: a first oscillation circuit operating the first piezoelectric resonator element of the pressure detection unit, a second oscillation circuit operating the second piezoelectric resonator element, a first frequency counter counting frequency of a stress detection signal outputted from the first oscillation circuit, a second frequency counter counting frequency of a temperature detection signal outputted from the second oscillation circuit, and a processing circuit correcting a frequency count signal outputted from the first frequency counter by a frequency count signal outputted from the second frequency counter.

13. A pressure sensor, comprising:
the pressure detection unit according to claim 2; and
a stress detection circuit, wherein
the stress detection circuit includes: an oscillation circuit operating one of the first and second piezoelectric resonator elements through a switcher, a frequency counter counting frequency of an output signal of one of the first and second piezoelectric resonators outputted from the oscillation circuit, and a processing circuit correcting a frequency count signal outputted from the frequency counter.
